(19) United States
(12) Patent Application Publication
(10) Pub. No.: US 2026/0050721 A1
(43) Pub. Date: Feb. 19, 2026

(54) SCALABLE DISTRIBUTED ENVIRONMENT FOR RESET DOMAIN CROSSING ANALYSIS AND INTERACTIVE DEBUG

(71) Applicant: Synopsys, Inc., Sunnyvale, CA (US)

(72) Inventors: Abhishek Kumar, Greater Noida (IN); Brijesh Agrawal, Greater Noida (IN); Anubhav Tihar, Greater Noida (IN); Anshul Garg, New Delhi (IN); Sean O'Donohue, Chino Hills, CA (US); Ajay Kumar, Noida (IN)

(73) Assignee: Synopsys, Inc., Sunnyvale, CA (US)

(21) Appl. No.: 19/170,474

(22) Filed: Apr. 4, 2025

(30) Foreign Application Priority Data
Jun. 4, 2024 (IN) 202441043212

(51) Int. Cl. G06F 30/33

(52) U.S. Cl. CPC G06F 30/33

(57) ABSTRACT

An integrated circuit (IC) design may be received by a first process. First reset domain crossing (RDC) analysis may be performed by the first process on the IC design to generate first RDC analysis results. A set of processes may be spawned by the first process, where a second process in the set of processes may read the first RDC analysis results, obtain information for an RDC scenario from the first process, perform second RDC analysis on the IC design based on the information for the RDC scenario to obtain second RDC analysis results, and send the second RDC analysis results to the first process. The second RDC analysis results received from the set of processes may be merged by the first process to obtain merged RDC analysis results.

### RELATED APPLICATION

This application claims the benefit of Indian Provisional Patent Application No. 202441043212, filed on 4 Jun. 2024, the contents of which are herein incorporated by reference in their entirety for all purposes.

### TECHNICAL FIELD

The present disclosure generally relates to an electronic design automation (EDA) system. More specifically, the present disclosure relates to a scalable distributed environment for reset domain crossing (RDC) analysis and interactive debug.

### BACKGROUND

EDA applications may be used to design and verify integrated circuit (IC) designs. It may be important to improve the performance of EDA applications.

### BRIEF DESCRIPTION OF THE FIGURES

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1A illustrates an IC design on which RDC analysis may be performed in accordance with some embodiments described herein.

FIG. 1B illustrates some waveforms corresponding to the IC design shown in FIG. 1A in accordance with some embodiments described herein.

FIG. 2 illustrates a distributed system for performing RDC analysis and interactive debug in accordance with some embodiments described herein.

FIG. 3 illustrates performing first RDC analysis on the IC design in accordance with some embodiments described herein.

FIG. 4 illustrates performing second RDC analysis on the IC design in accordance with some embodiments described herein.

FIG. 5 illustrates an example set of processes used during the design, verification, and fabrication of an article of manufacture such as an integrated circuit to transform and verify design data and instructions that represent the integrated circuit.

FIG. 6 illustrates an example machine of a computer system within which a set of instructions, for causing the machine to perform any one or more of the methodologies discussed herein, may be executed.

### DETAILED DESCRIPTION

Aspects of the present disclosure relate to a scalable distributed environment for RDC analysis and interactive debug. The term “sequential circuit element” may refer to a circuit element which may store a state, and which may be clocked by a clock signal. Examples of sequential circuit elements may include, but are not limited to, a flip-flop, a register, and a latch. A reset signal may be used to reset the state of one or more sequential circuit elements in an IC design. For example, in some embodiments, when a reset signal of a flip-flop is deasserted (or asserted in some embodiments), a desired value (e.g., logic 0 or 1) may be assigned to an output of the flip-flop. In some embodiments, asserting a signal may refer to assigning a logic 1 value to the signal, and deasserting the signal may refer to assigning a logic 0 value to the signal.

A reset domain may refer to a portion of an IC design which includes one or more sequential circuit elements which are reset by the same reset signal. An RDC may refer to the following situation: a data signal is launched by a first sequential circuit element and captured by a second sequential circuit element, where (1) the first sequential circuit element is reset by a first asynchronous reset signal and the second sequential circuit element is not resettable (i.e., a reset signal cannot be used to reset the second sequential element), or (2) the second sequential circuit element is reset by a second asynchronous reset signal which is independent of the first asynchronous reset signal. In this disclosure, ordinal numbers (such as “first,” “second,” and so forth) may be used to refer to entities or objects which may be distinct from one another; ordinal numbers may not necessarily imply an ordering between the entities or objects. The term “launch” may refer to an event (which may be triggered by a clock edge of a clock signal) in which the logic value stored in a sequential circuit element is assigned to an output of the sequential circuit element, and the term “capture” may refer to an event (which may be triggered by a clock edge of a clock signal) in which a logic value of an input of a sequential circuit element is stored in the sequential circuit element. Two signals may be independent of each other if the two signals are independently controllable with respect to each other, e.g., the first asynchronous reset signal and the second asynchronous reset signal may be independent of each other if the two asynchronous reset signals can be asserted and/or deasserted independently with respect to each other.

An RDC may cause metastability at an output of the second sequential circuit element (i.e., the sequential circuit element which captures the RDC data signal), and the metastability may propagate through one or more sequential circuit elements in the IC design. The term “metastability” may refer to the situation in which a signal has an unpredictable logic state. For example, metastability may occur at an output of a flip-flop if a hold timing constraint or a setup timing constraint is violated at an input of the flip-flop, which may cause the output of the flip-flop to transiently oscillate between a logic 0 and a logic 1 state and/or unpredictably settle at either the logic 0 or the logic 1 state.

It may be desirable to perform RDC analysis on an IC design to ensure that RDC-based metastabilities do not exist, or if they do exist, the RDC-based metastabilities do not cause the IC design to malfunction. Performing RDC analysis on an IC design may use a large amount of computing resources and/or time. Some embodiments described herein may substantially reduce the amount of computing resources and time used by a processing device for performing RDC analysis on an IC design. Specifically, some embodiments described herein may perform RDC analysis using a scalable distributed environment. Analysis tasks which are common to a set of RDC scenarios may be performed by a primary process. Multiple secondary processes may be spawned and executed in parallel, where each secondary process may handle one or more RDC scenarios, and may perform analysis tasks which are specific to the RDC scenarios which are being handled by the secondary process. The results of performing RDC analysis across the set of RDC scenarios may be merged and the merged results may be queried using a single interactive debug process.

Technical advantages of embodiments described herein may include, but are not limited to, (1) substantially reducing the amount of computing resources (e.g., processor cycles and/or memory usage) and/or time used for performing RDC analysis on an IC design, and (2) substantially reducing the amount of computing resources (e.g., processor cycles and/or memory usage) and/or time used for debugging RDC analysis results generated using a distributed environment.

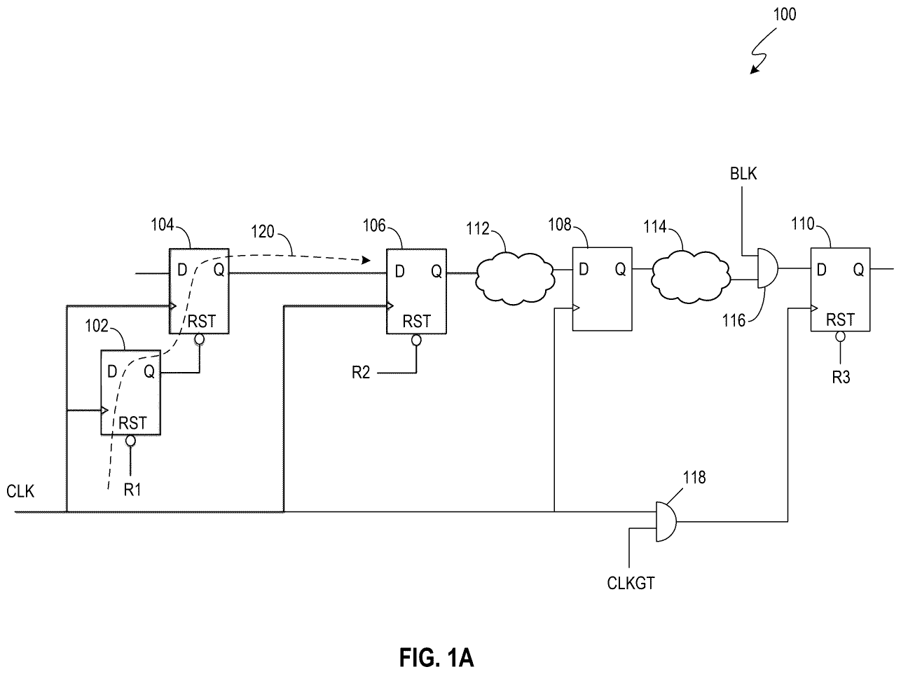

FIG. 1A illustrates an IC design on which RDC analysis may be performed in accordance with some embodiments described herein.

IC design 100 may include flip-flops 102, 104, 106, 108, and 110, and combinational logic circuits 112 and 114, and AND gates 116 and 118. The term “combinational logic circuit” may refer to a circuit which includes combinational logic gates (which may include, but are not limited to, AND gates, OR gates, and inverters) but does not include sequential circuit elements. Flip-flops 102, 104, 106, 108, and 110 may receive the same clock signal CLK (in general, different sequential circuit elements may receive the same or different clock signals). Flip-flops 102, 104, 106, and 110 may have reset pins, but flip-flop 108 may not have a reset pin. Asynchronous reset signal R1 may be provided to the reset pins of flip-flops 102 and asynchronous reset signal R2 may be provided to the flip-flop 106. Asynchronous reset signals R1, R2, and R3 may or may not be independent of each other. The Q output of flip-flop 102 may be provided as the reset signal to flip-flop 104.

FIG. 1B illustrates some waveforms corresponding to the IC design shown in FIG. 1A in accordance with some embodiments described herein.

Consider the situation where asynchronous reset signal R1 is independent of asynchronous reset signal R2, and asynchronous reset signal R1 is deasserted (e.g., R1 is assigned a logic 0 value), as shown by transition 152. If asynchronous reset signal R1 is deasserted, then the Q output of flip-flop 102 may be assigned a logic 0 value, as shown by transition 154. A logic 0 value at the Q output of flip-flop 102 may cause the reset input of flip-flop 104 to be deasserted. If the Q output of flip-flop 104 was equal to logic 1 before R1 was deasserted (which caused the reset input of flip-flop 104 to be deasserted), then deasserting R1 may propagate along path 120 and may cause the value at input D of flip-flop 106 to transition from a logic 1 value to a logic 0 value, as shown by transition 156. Transition 156 may happen substantially at the same time as clock edge 160, which may violate a setup time or hold time constraint associated with the input D of flip-flop 106, which may create metastability 158 in the Q output of flip-flop 104.

Metastability 158 may propagate through one or more flip-flops in IC design 100. For example, metastability 158 may propagate through combinational logic circuit 112, flip-flop 108, combinational logic circuit 114, and reach the bottom input of AND gate 116. If blocking signal BLK (which is provided to the top input of AND gate 116) is equal to logic 0, then metastability 158 may not propagate to the output of AND gate 116. On the other hand, if blocking signal BLK is equal to logic 1, then metastability 158 may propagate to the output of AND gate 116.

Consider the situation where blocking signal BLK is equal to logic 1. In this situation, metastability 158 may propagate to the output of AND gate 116 and reach the D input of flip-flop 110. Whether metastability 158 propagates to the Q output of flip-flop 110 may depend on asynchronous reset signal R3 and clock gating signal CLKGT. If asynchronous reset signal R3 is the same as asynchronous reset signal R1, then metastability 158 may not propagate to the Q output of flip-flop 110 because asynchronous reset signal R3 (which in this case is the same as asynchronous reset signal R1) may cause the Q output of flip-flop 110 to be assigned a logic 0 value regardless of the value of the D input of flip-flop 110. If clock gating signal CLKGT is assigned a logic 0 value (i.e., AND gate 118 is blocking the clock signal CLK), then clock edge 160 may not be provided to the clock input of flip-flop 110, and therefore the setup time and hold time constraints associated with flip-flop 110 are irrelevant at clock edge 160 and would not be violated. On the other hand, if asynchronous reset signal R3 is independent of asynchronous reset signal R1 and clock gating signal CLKGT is assigned a logic 1 value (i.e., AND gate 118 is not blocking the clock signal CLK), then a metastability at the D input of flip-flop 110 (e.g., metastability 158 which propagated to the D input of flip-flop 110) may propagate to the Q output of flip-flop 110.

It is noted that whether a metastability is created at an output of a flip-flop (e.g., metastability 158 at the Q output of flip-flop 104) and the extent to which the metastability propagates through the IC design may depend on multiple factors which may include, but are not limited to, transition timings of one or more reset signals, the timing of one or more clock edges, the value of one or more signals which may block the metastability along the data path, and the value of one or more clock gating signals in the clock tree. In some embodiments described herein, the term “RDC scenario” may include (1) transition timings of one or more reset signals (e.g., timing information for transition 152), (2) the timing of one or more clock edges (e.g., timing information for clock edge 160), (3) the value of one or more signals which may block the metastability along the data path (e.g., the signal BLK may block the metastability), and/or (4) the logic value of one or more clock gating signals in the clock tree (e.g., the logic value of signal CLKGT).

Performing RDC analysis for an RDC scenario may include determining whether a metastability is created in the RDC scenario and determining the extent to which the metastability propagates through the IC design. In some embodiments described herein may perform RDC analysis for a set of RDC scenarios. In some embodiments described herein, a primary process may perform processing which is common to all RDC scenarios, and the RDC scenario specific processing may be performed using a set of secondary processes. The results generated by the secondary processes may be merged, and the merged results may be debugged using a single process.

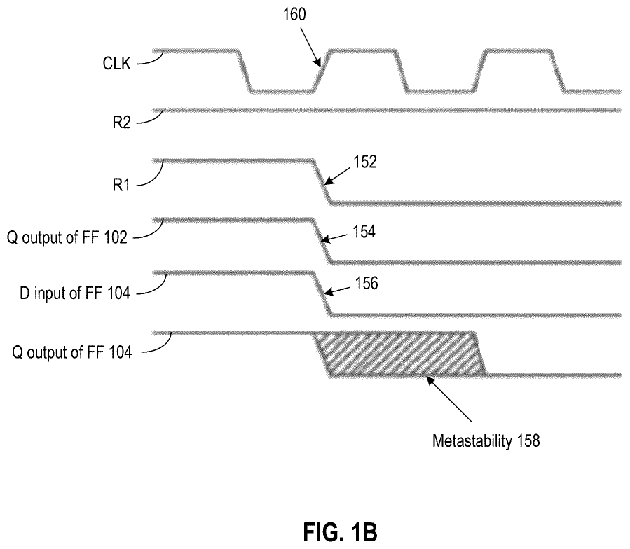

FIG. 2 illustrates a distributed system for performing RDC analysis and interactive debug in accordance with some embodiments described herein.

The distributed system for performing RDC analysis and interactive debug shown in FIG. 2 may include primary process 202 (also referred to as a first process herein) and a set of secondary processes, where the set of secondary processes may include secondary process 204 (also referred to as a second process herein) (other secondary processes are not shown in FIG. 2). The distributed system may include one or more computer systems (e.g., computer system 600), where each computer system may include one or more processing devices, and where each processing device may include one or more processing cores. The computing resources in a distributed system may be represented using a set of computing nodes, where each process may be assigned (or mapped) to, and executed on, a computing node. In some embodiments described herein, the primary process and the set of secondary processes may be assigned (or mapped) to, and executed on, different computing nodes. Specifically, primary process 202 may be executed on a first computing node and secondary process 204 may be executed on a second computing node.

Primary process 202 may read an IC design (at 206) and represent the IC design using a data model, where the data model may include a graph structure where nodes of the graph structure represent components of the IC design and where the edges of the graph structure represent how the components are interconnected. Primary process 202 may perform first RDC analysis on the IC design, where the first RDC analysis may include common tasks across a set of RDC scenarios (at 208). In other words, performing RDC analysis for any of the RDC scenarios in the set of RDC scenarios may include performing the same set of operations, and these operations may be performed once by primary process 202 (instead of being performed by each secondary process separately).

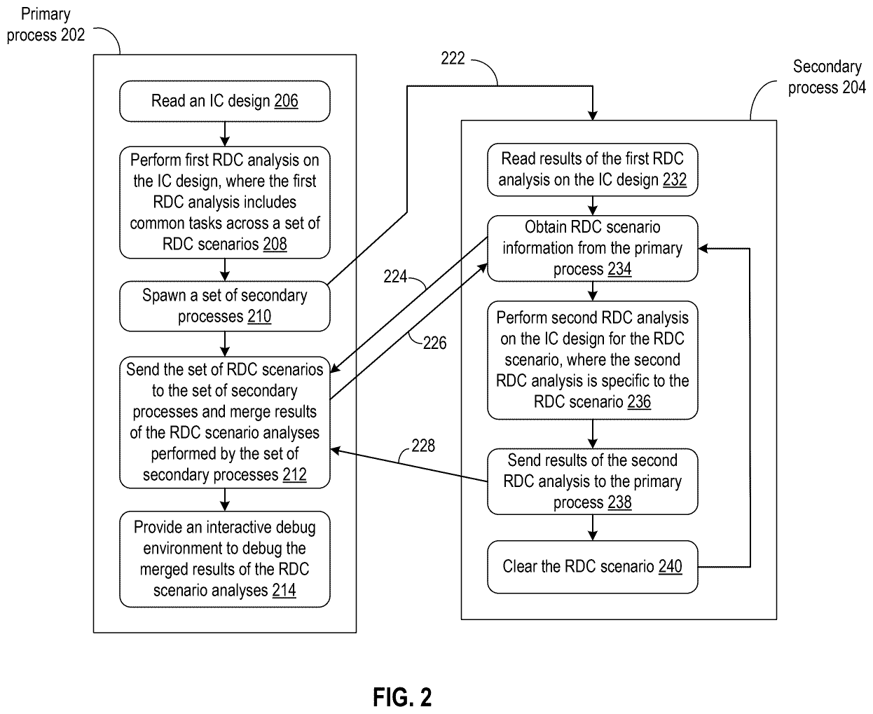

FIG. 3 illustrates performing first RDC analysis on the IC design in accordance with some embodiments described herein.

The process illustrated in FIG. 3 may be performed by a primary process (e.g., primary process 202). Constant propagation may be performed using the data model of the IC design (at 302). In some embodiments described herein, the IC design itself or statements which are provided in addition to the IC design (e.g., Tool Command Language (Tcl) statements) may indicate the value of one or more signals in the IC design. The effect of these signals may be propagated through the IC design. For example, the IC design itself or a Tcl statement may indicate that signal BLK in IC design 100 is equal to logic 0 for all RDC scenarios in the set of RDC scenarios. During constant propagation, any constant signals specified in the IC design may be identified and/or design constraints (e.g., Tcl statements) may be parsed to identify constant signals, and the identified constant signals may be propagated through the IC design using the data model for the IC design. For example, the BLK value of logic 0 may be propagated through AND gate 116 to determine that the input D of flip-flop 110 is equal to logic 0 in all RDC scenarios in the set of RDC scenarios.

Clock propagation may be performed using the data model of the IC design (at 304). The data model may specify a set of clock signals, and specify which clock pin in the IC design receives which clock signal. The frequency of the clock signal waveforms and the duty cycle of the clock signal waveforms may be provided using a set of clock design constraints. During clock propagation, the clock tree structures may be determined, and the set of clock design constraints may be analyzed to determine the timing of clock edges. For example, the tree structure of the clock network which distributes the clock signal CLK in IC design 100 may be determined, and the timing of the clock edges at the clock inputs of flip-flops 102, 104, 106, 108, and 110 may be determined.

Reset propagation may be performed using the data model of the IC design (at 306). The data model may specify a set of reset signals, and specify which reset pin in the IC design receives which reset signal. The timing of when a reset signal is deasserted or asserted may be provided using a set of reset design constraints. During reset propagation, the reset tree structures may be determined, and the set of reset design constraints may be analyzed to determine the timing of reset signal transitions. For example, the tree structures of the reset networks which distribute the reset signals R1, R2, and R3 in IC design 100 may be determined, and the timing of the reset signal transitions at the reset inputs of flip-flops 102, 104, 106, and 110 may be determined.

RDC-scenario-independent structural verification of the IC design may be performed using the data model of the IC design (at 308). The IC design may include errors which may prevent RDC analysis from being correctly performed on the IC design. For example, RDC-scenario-independent structural verification may ensure that there are no floating clock/reset pins (e.g., a clock/reset pin which is not electrically connected to any clock/reset signal). Specifically, during RDC-scenario-independent structural verification, the IC design may be analyzed to identify structural problems and/or electrical deign rule violations in the IC design, which may include, but are not limited to, detecting/identifying floating input pins and/or floating nets and/or unloaded output pins, detecting/identifying that there are no shorts between power and ground, detecting/identifying that a net is not driven by multiple drivers, and detecting/identifying that no combinational loops exist in the IC design.

The results of constant, clock, and reset propagation may be serialized, and the serialized results may be stored (at 310). For example, the results of constant propagation, clock propagation, and reset propagation may be stored in one or more objects and/or data structures in memory. These objects and/or data structures may be serialized and the serialized objects and/or data structures may be stored on disk. The term “serialization” may refer to a process of converting a data structure or object (which may have a complex structure) into a sequence of bytes which may be stored on disk or sent over a communication channel. A first process (e.g., the primary process) may serialize objects and/or data structures, and a second process (e.g., a secondary process) may read the serialized objects and/or data structures and recreate the objects and/or data structures.

Continuing with the description of FIG. 2, a set of secondary processes may be spawned (at 210). For example, at 222, primary process 202 may spawn secondary process 204 (only one secondary process is shown in FIG. 2, but the system may include multiple secondary processes). Each secondary process may execute on a different computing node and may execute in parallel to the primary process and other secondary processes. In some embodiments described herein, the set of scenarios may be partitioned among the secondary processes. In some embodiments described herein, the secondary processes may automatically and dynamically partition the set of scenarios by requesting a next scenario from the primary process once the analysis of the current scenario is completed. The term “execute in parallel” may mean that multiple processes may execute separately and simultaneously on different processing devices or cores.

A secondary process in the set of secondary processes, e.g., secondary process 204, may read results of the first RDC analysis on the IC design (at 232). For example, secondary process 204 may read the serialized objects and/or data structures (which were serialized and stored by primary process 202), deserialize the serialized objects and/or data structures, and recreate the objects and/or data structures internally within secondary process 204. In other words, the objects and/or data structures recreated by secondary process 204 may represent the results of performing first RDC analysis on the IC design. It is noted that the amount of time used by a secondary process (e.g., secondary process 204) to read the serialized objects and/or data structures and recreate the objects and/or data structures internally within the secondary process may be substantially less than the time which would have been used by the secondary process to perform the first RDC analysis on the IC design. Moreover, the results of performing first RDC analysis on the IC design are stored once by the primary process (as opposed to being stored separately by each secondary process), which may substantially reduce the amount of storage used for storing the results of performing first RDC analysis on the IC design.

A secondary process (e.g., secondary process 204) may obtain RDC scenario information from the primary process (at 234). For example, secondary process 204 may send a request 224 to primary process 202, where request 224 indicates that secondary process 204 is ready to perform second RDC analysis on an RDC scenario. Primary process 202 may send a response 226 which may include information of an RDC scenario. In some embodiments described herein, the RDC scenario information may include transition timings of one or more reset signals. In some embodiments, the RDC scenario information may additionally include the timing of one or more clock edges, the value of one or more signals which may block the metastability along the data path, and/or the logic value of one or more clock gating signals in the clock tree. The secondary process (e.g., secondary process 204) may perform second RDC analysis on the IC design for the RDC scenario, where the second RDC analysis is specific to the RDC scenario (at 236).

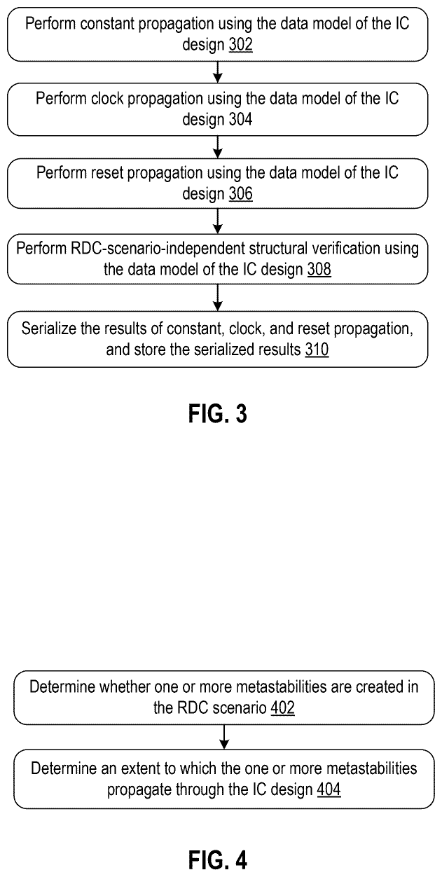

FIG. 4 illustrates performing second RDC analysis on the IC design in accordance with some embodiments described herein.

The process illustrated in FIG. 4 may be performed by each secondary process (e.g., secondary process 204). A secondary process (e.g., secondary process 204) may determine whether one or more metastabilities are created in the RDC scenario (at 402). For example, secondary process 204 may use transition timings of one or more reset signals, timings of one or more clock edges, the value of one or more signals which may block the metastability along the data path, and/or the logic value of one or more clock gating signals in the clock tree to determine whether one or more metastabilities are created as explained in reference to FIG. 1A. In some embodiments described herein, secondary process 204 may simulate the IC design for one or more clock cycles based on the information for the RDC scenario to determine (1) whether one or more metastabilities (e.g., a signal glitch or an incorrect state of a flip-flop) are created, (2) an extent to which the one or more metastabilities are propagated through the IC design, and (3) one or more waveforms of one or more signals in the IC design which correspond to the RDC scenario.

The secondary process may determine the extent to which the one or more metastabilities propagate through the IC design (at 404). For example, as explained in reference to FIG. 1A, a metastability created at the Q output of flip-flop 104 may or may not propagate to the D input of flip-flop 110 depending on the value of the BLK signal, and may or may not propagate to the Q input of flip-flop 110 depending on the CLKGT signal and the R3 signal.

Continuing with the description of FIG. 2, the secondary process (e.g., secondary process 204) may send results 228 of the second RDC analysis to the primary process, e.g., primary process 202 (at 238). The secondary process (e.g., secondary process 204) may clear the RDC scenario (at 240) and return to obtaining the next RDC scenario information from the primary process (at 234). Clearing the RDC scenario may include freeing up memory resources and/or clearing any variables or computations which were performed for the RDC scenario, so that the secondary process can load the next RDC scenario automatically and does not require user intervention. It is noted that the secondary process may read the results of the first RDC analysis on the IC design only once, and then process multiple RDC scenarios by repeatedly obtaining RDC scenario information from the primary process, performing second RDC analysis on the IC design for the RDC scenario, where the second RDC analysis is specific to the RDC scenario, sending results of the second RDC analysis to the primary process, clearing the RDC scenario. The secondary process (e.g., secondary process 204) may terminate once the primary process does not have any more RDC scenarios which need to be analyzed.

As shown in FIG. 2, the primary process (e.g., primary process 202) may send the set of RDC scenarios (e.g., response 226) to the set of secondary processes and merge results (e.g., merging duplicate violations) of the RDC scenario analyses performed by the set of secondary processes (at 212). Specifically, the primary process (e.g., primary process 202) may maintain a queue with the set of RDC scenarios which are desired to be analyzed, and send them to the secondary processes one by one in response to the secondary processes sending requests (e.g., request 224) to analyze the next RDC scenario.

The primary process (e.g., primary process 202) may provide an interactive debug environment to debug the merged results of the RDC scenario analyses (at 214). In some embodiments described herein, duplicate violations received from different scenarios (which may have been processed by the same or different secondary processes) may be merged into a single violation entry. In a graphical user interface (GUI), the merged violation entry may be associated with the set of scenarios which were merged. The GUI may enable a user to select a merged violation to show the set of scenarios which generated the merged violation entry. Specifically, in some embodiments described herein, an identifier may be generated for each violation and violations which have the same identifier value may be merged. In some embodiments described herein, a violation signature may be computed (e.g., using a hash function such as SHA-1) based on one or more violation fields to uniquely identify a violation. The violation signature may be used for merging violations across scenarios.

The primary process (e.g., primary process 202) may enable debugging of the IC design for any of the RDC scenarios which were analyzed by the distributed system. The primary process may provide an interactive debug environment by integrating information about the IC design which is common to all RDC scenarios with the RDC scenario information which is specific to each RDC scenario. For example, when a specific RDC violation for a specific RDC scenario is selected (e.g., by a user via the GUI), the primary process may display information in the GUI which is common to all RDC scenarios (e.g., circuit design elements and the signal path) and RDC scenario information (e.g., reset transition timing and/or waveform) which caused the specific RDC violation.

In some embodiments described herein, the primary process (e.g., primary process 202) may monitor the health of the set of secondary processes (e.g., secondary process 204). For example, the set of secondary processes may be expected to provide periodic heartbeat (feedback) messages to the primary process. If the primary process does not receive a heartbeat message from a secondary process within a certain time duration, then the primary process may determine that the secondary process is not operating as desired (e.g., the secondary process may have crashed). If the primary process determines that a secondary process has crashed, then the primary process may perform clean-up operations on the computing node which was executing the secondary process (e.g., the primary process may kill any zombie processes associated with the secondary process) and restart a new secondary process on the computing node which may then continue processing RDC scenarios. In some embodiments described herein, a primary process may detect abnormal termination of secondary processes (which may happen because an application crashed or ran out of memory resources) and provide the status to a user upon request.

In some embodiments described herein, an IC design may be received by a first process. First RDC analysis on the IC design may be performed by the first process to generate first RDC analysis results. A set of processes may be spawned by the first process, where a second process in the set of processes may read the first RDC analysis results, obtain information for an RDC scenario from the first process, perform second RDC analysis on the IC design based on the information for the RDC scenario to obtain second RDC analysis results, and send the second RDC analysis results to the first process. The second RDC analysis results received from the set of processes may be merged by the first process to obtain merged RDC analysis results.

In some embodiments described herein, the first process may execute on a first computing node and the second process may execute on a second computing node. In some embodiments described herein, the information for the RDC scenario may include at least a transition timing of at least one reset signal. In some embodiments described herein, performing the first RDC analysis may include performing constant propagation through the IC design. In some embodiments described herein, performing the first RDC analysis may include performing clock propagation through the IC design. In some embodiments described herein, performing the first RDC analysis may include performing reset propagation through the IC design.

In some embodiments described herein, performing the second RDC analysis may include determining whether one or more metastabilities are created in the IC design. In some embodiments described herein, performing the second RDC analysis may include determining an extent to which the one or more metastabilities propagate through the IC design. In some embodiments described herein, performing the second RDC analysis may include simulating the IC design for one or more clock cycles based on the information for the RDC scenario.

In some embodiments described herein, a third process may provide a debug environment to debug RDC violations in the IC design based on the merged RDC analysis results.

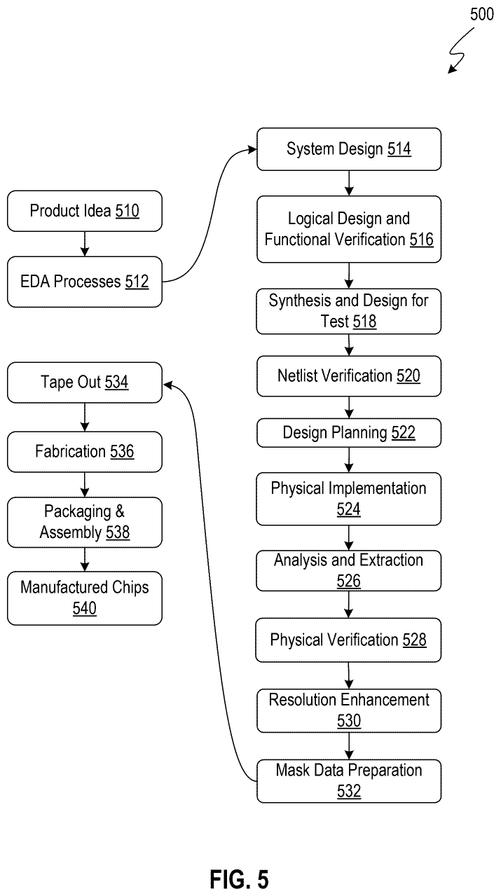

FIG. 5 illustrates an example set of processes 500 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 510 with information supplied by a designer, information which is transformed to create an article of manufacture that uses a set of EDA processes 512. When the design is finalized, the design is taped-out 534, which is when artwork (e.g., geometric patterns) for the integrated circuit is sent to a fabrication facility to manufacture the mask set, which is then used to manufacture the integrated circuit. After tape-out, a semiconductor die is fabricated 536 and packaging and assembly processes 538 are performed to produce the finished integrated circuit 540.

Specifications for a circuit or electronic structure may range from low-level transistor material layouts to high-level description languages. A high-level of representation may be used to design circuits and systems, using a hardware description language (‘HDL’) such as VHDL, Verilog, System Verilog, SystemC, MyHDL or Open Vera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 5. The processes described by be enabled by EDA products (or EDA systems).

During system design 514, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 516, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 518, HDL code is transformed to a netlist. In some embodiments, a netlist may be a graph structure where nodes of the graph structure represent components of a circuit and where the edges of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 520, the netlist is checked for compliance with timing constraints and for correspondence with the HDL code. During design planning 522, an overall floor plan for the integrated circuit is constructed and analyzed for timing and top-level routing.

During layout or physical implementation 524, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 526, the circuit function is verified at the layout level, which permits refinement of the layout design. During physical verification 528, the layout design is checked to ensure that manufacturing constraints are correct, such as DRC constraints, electrical constraints, lithographic constraints, and that circuitry function matches the HDL design specification. During resolution enhancement 530, the geometry of the layout is transformed to improve how the circuit design is manufactured.

During tape-out, data is created to be used (after lithographic enhancements are applied if appropriate) for production of lithography masks. During mask data preparation 532, the ‘tape-out’ data is used to produce lithography masks that are used to produce finished integrated circuits.

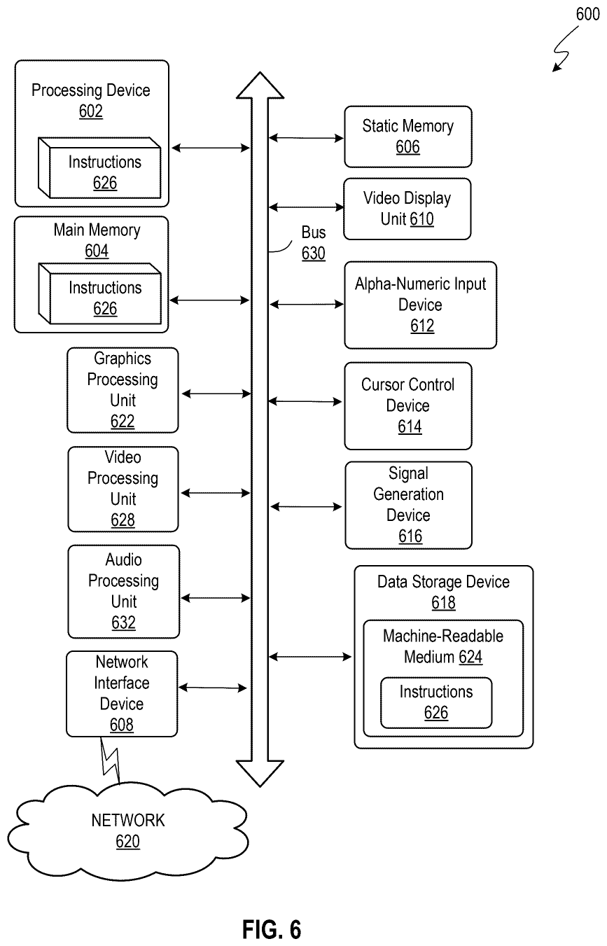

A storage subsystem of a computer system (such as computer system 600 of FIG. 6) may be used to store the programs and data structures that are used by some or all of the EDA products described herein, and products used for development of cells for the library and for physical and logical design that use the library.

FIG. 6 illustrates an example machine of a computer system 600 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM), a static memory 606 (e.g., flash memory, static random access memory (SRAM), etc.), and a data storage device 618, which communicate with each other via a bus 630.

Processing device 602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. The processing device 602 may be configured to execute instructions 626 for performing the operations and steps described herein.

The computer system 600 may further include a network interface device 608 to communicate over the network 620. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), a graphics processing unit 622, a signal generation device 616 (e.g., a speaker), graphics processing unit 622, video processing unit 628, and audio processing unit 632.

The data storage device 618 may include a machine-readable storage medium 624 (also known as a non-transitory computer-readable medium) on which is stored one or more sets of instructions 626 or software embodying any one or more of the methodologies or functions described herein. The instructions 626 may also reside, completely or at least partially, within the main memory 604 and/or within the processing device 602 during execution thereof by the computer system 600, the main memory 604 and the processing device 602 also constituting machine-readable storage media.

In some implementations, the instructions 626 include instructions to implement functionality corresponding to the present disclosure. While the machine-readable storage medium 624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 602 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method, comprising:
receiving, by a first process, an integrated circuit (IC) design;
performing, by the first process, first reset domain crossing (RDC) analysis on the IC design to generate first RDC analysis results;
spawning, by the first process, a set of processes, wherein a second process in the set of processes:
reads the first RDC analysis results;
obtains information for an RDC scenario from the first process;
performs second RDC analysis on the IC design based on the information for the RDC scenario to obtain second RDC analysis results; and
sends the second RDC analysis results to the first process; and
merging the second RDC analysis results received from the set of processes to obtain merged RDC analysis results.

2. The method of claim 1, wherein the first process executes on a first computing node and the second process executes on a second computing node.

3. The method of claim 1, wherein the information for the RDC scenario includes at least a transition timing of at least one reset signal.

4. The method of claim 1, wherein performing the first RDC analysis includes performing constant propagation through the IC design.

5. The method of claim 1, wherein performing the first RDC analysis includes performing clock propagation through the IC design.

6. The method of claim 1, wherein performing the first RDC analysis includes performing reset propagation through the IC design.

7. The method of claim 1, wherein performing the second RDC analysis includes determining whether one or more metastabilities are created in the IC design.

8. The method of claim 7, wherein performing the second RDC analysis includes determining an extent to which the one or more metastabilities propagate through the IC design.

9. The method of claim 1, wherein performing the second RDC analysis includes simulating the IC design for one or more clock cycles based on the information for the RDC scenario.

10. The method of claim 1, further comprising providing, by a third process, a debug environment to debug RDC violations in the IC design based on the merged RDC analysis results.

11. A non-transitory computer-readable medium comprising stored instructions, which when executed by a set of computing nodes, cause the set of computing nodes to:
receive, by a first process, an integrated circuit (IC) design;
perform, by a first process, first reset domain crossing (RDC) analysis on the IC design to generate first RDC analysis results;
spawn, by the first process, a set of processes, wherein a second process in the set of processes:
reads the first RDC analysis results;
obtains information for an RDC scenario from the first process;
performs second RDC analysis on the IC design based on the information for the RDC scenario to obtain second RDC analysis results; and
sends the second RDC analysis results to the first process; and
merge the second RDC analysis results received from the set of processes to obtain merged RDC analysis results.

12. The non-transitory computer-readable medium of claim 11, wherein the first process executes on a first computing node and the second process executes on a second computing node.

13. The non-transitory computer-readable medium of claim 11, wherein the information for the RDC scenario includes at least a transition timing of at least one reset signal.

14. The non-transitory computer-readable medium of claim 11, wherein performing the first RDC analysis includes performing constant propagation through the IC design.

15. The non-transitory computer-readable medium of claim 11, wherein performing the first RDC analysis includes performing clock propagation through the IC design.

16. The non-transitory computer-readable medium of claim 11, wherein performing the first RDC analysis includes performing reset propagation through the IC design.

17. The non-transitory computer-readable medium of claim 11, wherein performing the second RDC analysis includes determining whether one or more metastabilities are created in the IC design.

18. The non-transitory computer-readable medium of claim 17, wherein performing the second RDC analysis includes determining an extent to which the one or more metastabilities propagate through the IC design.

19. The non-transitory computer-readable medium of claim 11, further comprising providing, by a third process, a debug environment to debug RDC violations in the IC design based on the merged RDC analysis results.

20. A system, comprising:
a memory storing instructions; and
a set of processing devices, coupled with the memory and to execute the instructions, the instructions when executed causing the set of processing devices to:
receive, by a primary process, an integrated circuit (IC) design;
perform, by a primary process, first reset domain crossing (RDC) analysis on the IC design to generate first RDC analysis results;
spawn, by the primary process, a set of secondary processes, wherein a secondary process in the set of secondary processes:
reads the first RDC analysis results;
obtains information for an RDC scenario from the primary process;
performs second RDC analysis on the IC design based on the information for the RDC scenario to obtain second RDC analysis results, wherein performing the second RDC analysis includes determining whether one or more metastabilities are created in the IC design; and
sends the second RDC analysis results to the primary process; and
merge the second RDC analysis results received from the set of processes to obtain merged RDC analysis results.
